(19) United States
(12) Patent Application Publication
(10) Pub. No.: US 2012/0166693 A1
(43) Pub. Date: Jun. 28, 2012

(54) Intelligent Asset Management System

(75) Inventors: Neil Weinstock, Randolph, NJ (US); Swen Anderson, Burgstadt (DE)

(73) Assignee: Raritan Americas, Inc., Somerset, NJ (US)

(21) Appl. No.: 13/191,225

(22) Filed: Jul. 26, 2011

Related U.S. Application Data
(60) Provisional application No. 61/451,922, filed on Mar. 11, 2011.
(60) Provisional application No. 61/367,556, filed on Jul. 26, 2010.

(51) Int. Cl. G06F 13/42; G08B 21/00; G06K 19/00; G06K 7/01

(52) U.S. Cl. 710/105; 340/10.1; 340/687; 710/107; 235/487

(57) ABSTRACT

A system and method of associating the identification of a server with its physical location thorough the use of an asset management strip and asset management tags. The asset management strip is extendable by means of slave asset management strips. The asset tags are attached to data center components, such as servers, in racks. They are removably attached to the asset strip and provide identification information to the asset strip. The asset strip can correlate the identification information with the location where the tag attaches to the strip. The strip provides the rack identity to management software over a network, which includes an indication of a vertical location on the rack of the component and the component identification data.

### CROSS-REFERENCE TO RELATED APPLICATIONS

This application claims the benefit of priority under §119(e) to U.S. Provisional Patent Application No. 61/367,556 filed Jul. 26, 2010 and to U.S. Provisional Patent Application No. 61/451,922 filed Mar. 11, 2011, both of which are hereby incorporated by reference in their entireties herein.

### BACKGROUND OF THE INVENTION

The invention relates to the management of data center infrastructure. More specifically it relates to systems, apparatuses and methods for establishing and tracking the identity of components in the data center.

A data center is a location used to house computer systems, typically arranged in a number of racks. The management of data centers is a well established discipline. Part of the task of the management of data centers is the tracking of often thousands of discrete electronic components, such as servers, switches, storage devices, power supplies, and others. These discrete components must all be tracked in, for example, data center infrastructure management (“DCIM”) software. Such tracking is necessary for the effective operation and maintenance of a data center. For example, if a specific server starts generating errors detected over a network derived from hardware failure, then that server location must be known so that a technician can effect repairs/replacement. Thus the DCIM software must know both the identity of the server and its physical location.

A 19-inch rack is a standardized frame or enclosure for mounting multiple equipment components in a data center environment. Each component has a front panel that is 19 inches (482.6 mm) wide, including edges or ears that protrude on each side which allow the module to be fastened to the rack frame with screws. A “rack unit” or “U” (less commonly “RU”) is a unit of measure used to describe the height of equipment intended for mounting in a 19-inch rack or a 23-inch rack. One rack unit is 1.75 inches (44.45 mm) high. The size of a piece of rack-mounted equipment is frequently described as a number in “U”. For example, one rack unit is often referred to as “1U”, 2 rack units as “2U” and so on. The location of a component is typically given by a rack number which identifies the rack in the DCIM database, which in turn gives the rack location (previously inputted, and by a rack vertical number to determine how high up the component is placed (for example, a 7U position).

Typically, the identity and location data and the correlation between the two must be entered manually in such data center software. For example, if a new server or other component is mounted in a rack in a data center, the identification of the server and its location in the rack must be manually entered into the DCIM software. Such data entry is time-consuming, expensive, and prone to error. There remains in the art of data center operations a need to automate the entry of this correlation into DCIM software.

### SUMMARY OF THE INVENTION

In one or more specific embodiments further described herein, the present invention provides for an asset management system. The asset management system includes an intelligent asset management strip (“asset strip” or “strip”), intelligent asset management tags (“tags”), and management software, all used to track a data center component such as a server mounted in a rack. The asset strip has arrayed on its front a number of identification connectors adjacently spaced 1 rack unit apart along the length of the strip. A serial data connector is arrayed on the front at one end of the length of the strip. It is attached to a front post of the rack such that the strip is arrayed with its long dimension oriented vertically with the serial data connector at the bottom end. The flexible tag is attached to a server mounted in the rack, and has a tag identification connector and an identification circuit coupled to it. The tag identification connector is removably coupled to the identification connector of the asset strip that is positioned at the server's height on the rack. The tag then provides identification data from the identification circuit to the asset strip. The asset strip implicitly associates the identification data with the location of the server. More specifically, the location of the identification connector which receives the identification data is of a known location on the asset strip.

Another embodiment of the present invention provides for the asset management system described above having an asset strip including a number of LED controllers and a second number of LEDs. The LEDs are deployed on the strip such that each is proximally positioned adjacently to an associated identification connector.

Another embodiment of the present invention provides for an asset strip having a microcontroller, a data bus, a control bus, a multiplexer, and a number of identification connectors coupled to the multiplexer by the same number of branch data buses. The multiplexer is coupled to the data bus and the control bus. The microcontroller determines which of the identification connectors and thus which branch data bus is connected to the data bus. Thus the microcontroller, when receiving identification data, can associate that data with a location along the strip.

### BRIEF DESCRIPTION OF THE DRAWINGS

For the purposes of illustration, there are forms shown in the drawings that are presently preferred, it being understood, however, that the invention is not limited to the precise arrangements and instrumentalities shown.

FIG. 1 is a perspective view of an asset management strip according to an embodiment of the present invention.

FIG. 2 is a planar view of an asset management strip according to the embodiment of FIG. 1.

FIG. 3 is an enlarged view of a portion of the asset management strip of FIG. 2.

FIG. 4 is a perspective view of an asset management tag according to an embodiment of the present invention.

FIGS. 5A and 5B are opposing planar views of the asset management tag of FIG. 4.

FIG. 5C is an planar view of an alternative embodiment asset management tag of FIG. 4.

FIG. 6 is a planar view of a rack incorporating an asset management strip and asset management tags according to an embodiment of the present invention.

FIG. 7 is a cut away schematic view of an asset management strip and an asset management tag according to an embodiment of the present invention.

FIG. 8 is a schematic view of an asset management strip according to an embodiment of the present invention.

FIG. 9 is a schematic of an asset management tag according to an embodiment of the present invention.

FIG. 10 is a perspective view of a slave asset management strip according to an embodiment of the present invention.

FIG. 11 is a planar view of the slave asset management strip of FIG. 10.

FIG. 12 is a planar view of a rack incorporating an asset management strip and asset management tags according to an embodiment of the present invention.

FIG. 13 is a schematic view of a slave asset management strip according to an embodiment of the present invention.

FIG. 14 is a schematic diagram of a portion of a data center using asset management strips and asset management tags according to an embodiment of the present invention.

FIG. 15 is a partial schematic view of an asset management strip and a slave management strip according to an embodiment of the present invention.

FIG. 16 is a flowchart of one embodiment of the present invention.

### DETAILED DESCRIPTION OF PREFERRED EMBODIMENTS

Reference will now be made in detail to exemplary embodiments of the invention. Examples of these exemplary embodiments are illustrated in the accompanying drawings. While the invention is described in conjunction with these embodiments, it will be understood that it is not intended to limit the invention to the described embodiments. Rather, the invention is also intended to cover alternatives, modifications, and equivalents as may be included within the spirit and scope of the invention as defined by the appended claims.

In the following description, specific details are set forth in order to provide a thorough understanding of the present invention. The present invention may be practiced without some or all of these specific details. In other instances, well-known aspects have not been described in detail in order not to unnecessarily obscure the present invention.

In this specification and the appended claims, the singular forms “a,” “an,” and “the” include plural references unless the context clearly dictates otherwise. Unless defined otherwise, all technical and scientific terms used herein have the same meaning as commonly understood to one of ordinary skill in the art to which this invention belongs. The term “couple” or “couples” is intended to mean either an indirect or direct electrical connection. Thus, if a first device couples to a second device, that connection may be through a direct electrical connection, or through an indirect electrical connection via other devices and connections.

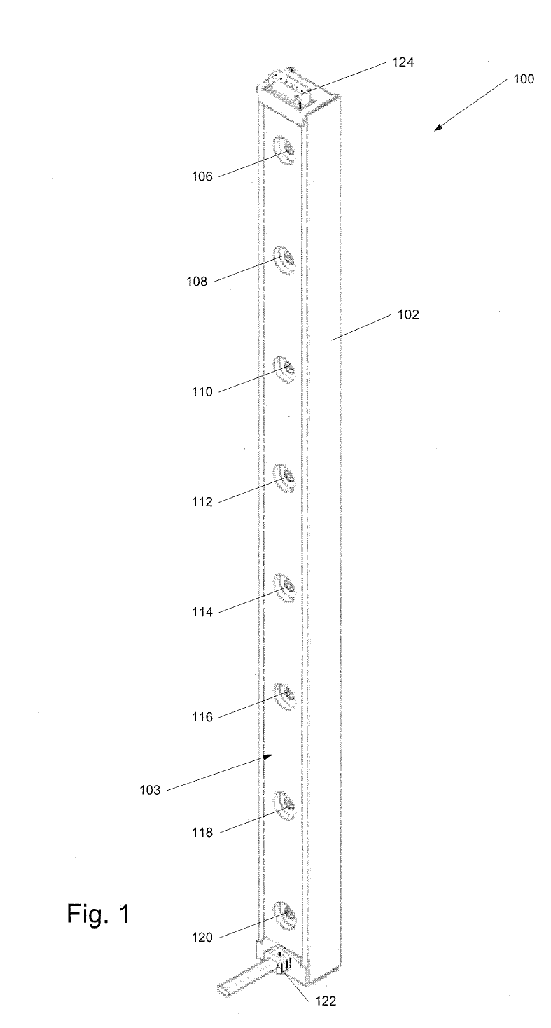

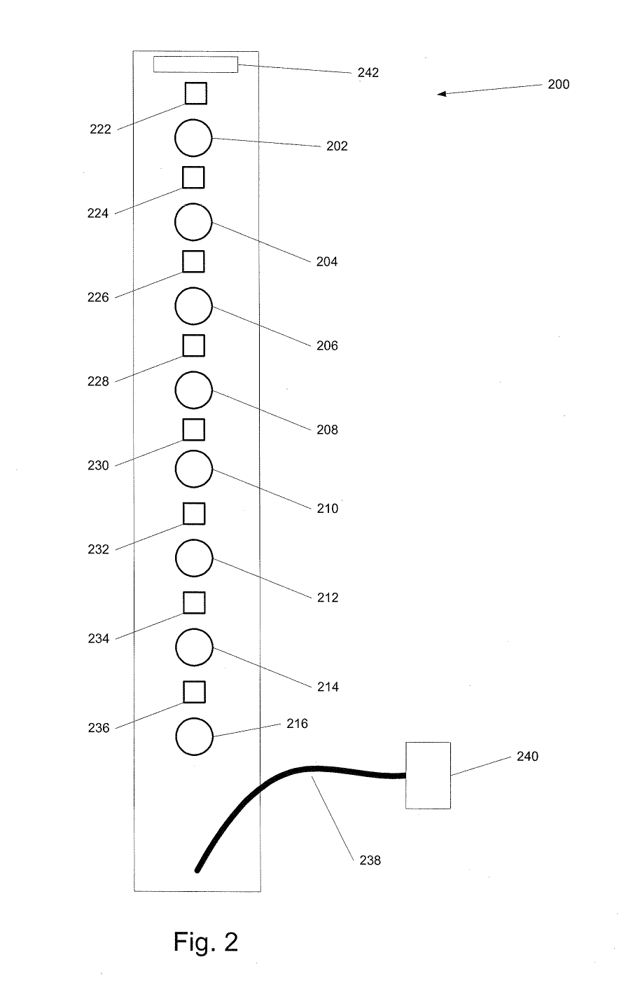

FIG. 1 shows an intelligent asset management strip 100 as one embodiment of the present invention. The outer enclosure 102 has on one side of its length identification connectors 106-120. On the same side as the identification connectors 106-120 at one end of the strip 100 is Serial data connection 122. At the opposite end of the strip 100 is inter-strip connector 124. In this embodiment the front 103 of the enclosure 102 is preferably made of translucent material, and may alternatively be made of a transparent material. FIG. 2 shows a more detailed view of an intelligent asset management strip 200 with other components shown through the translucent material of the front 103. identification connectors 202-216 are shown as positioned in relating to associated multicolor LED's 222-236. Serial data connection 238 terminates with serial data jack 240. Inter-strip connector 242 is also shown. It will be obvious to one skilled in the art that the front 103 could have multiple apertures for the LEDs, and in that case made of a non-translucent or non-transparent material. In the present embodiment employing translucent material, the front 103 is used to protect LEDs to 222-236.

Returning to FIG. 1, the identification connectors 106-120 of strip 100 are approximately 1U in distance from each other. This physical spacing allows a correlation of each identification connector and associated LED location with the location of a tagged server.

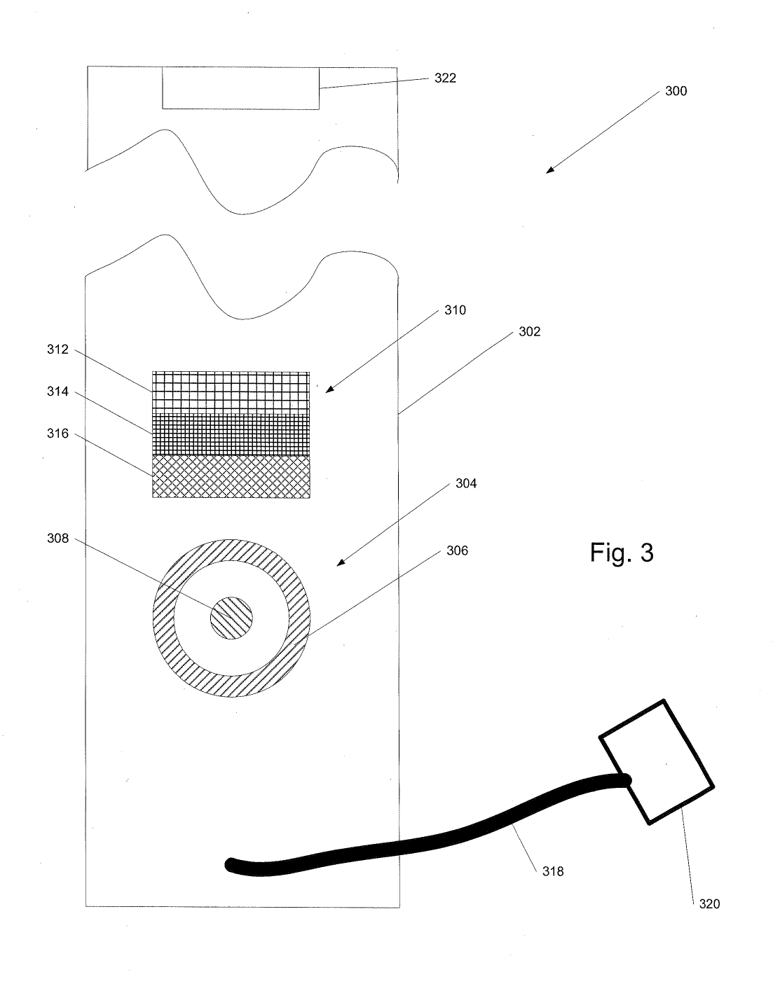

FIG. 3 shows a close-up of an intelligent asset management strip 300 omitting the front 103 of translucent enclosure. The body 302 of strip 300 has a front 304. On this front 304 are deployed a magnetic ring 306 surrounding a spring-loaded contact 308. Also deployed in this front are multicolor LED 310 which is composed of red LED 312, Green LED 314 and blue LED 316. Serial data connector 318 terminates in jack 320. Inter-strip connector 322 is deployed at the top of the strip 300.

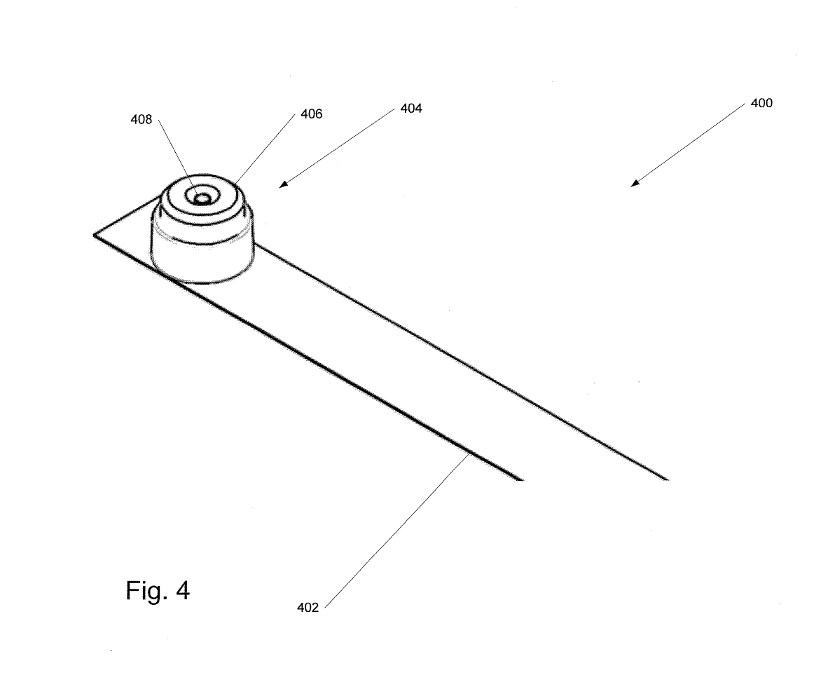

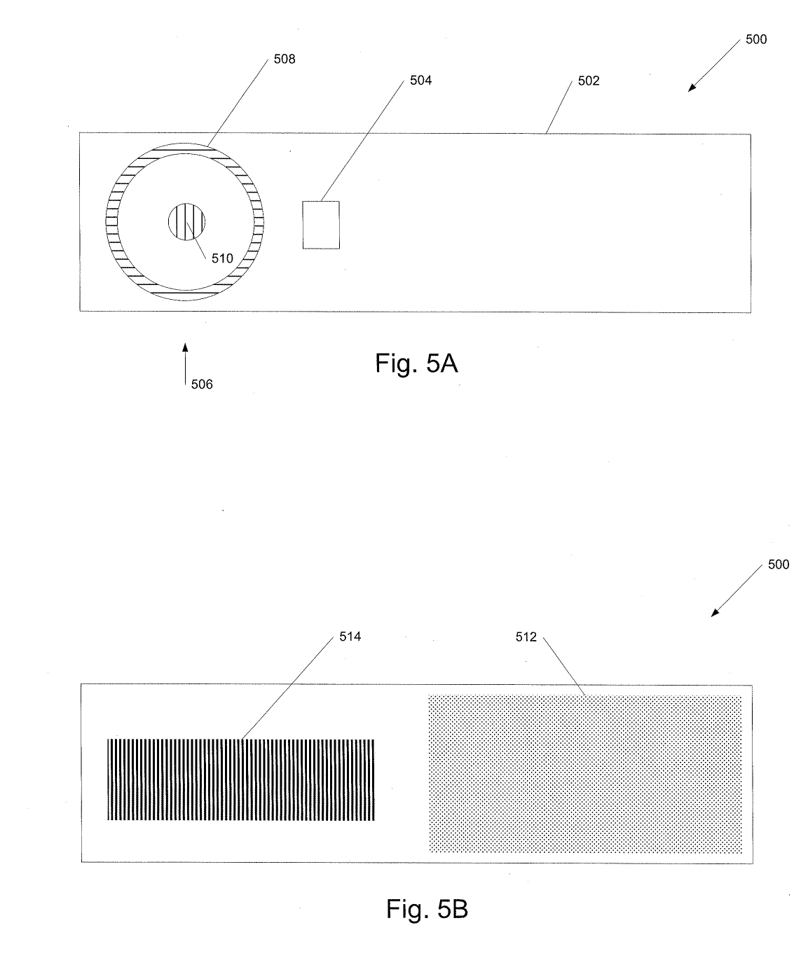

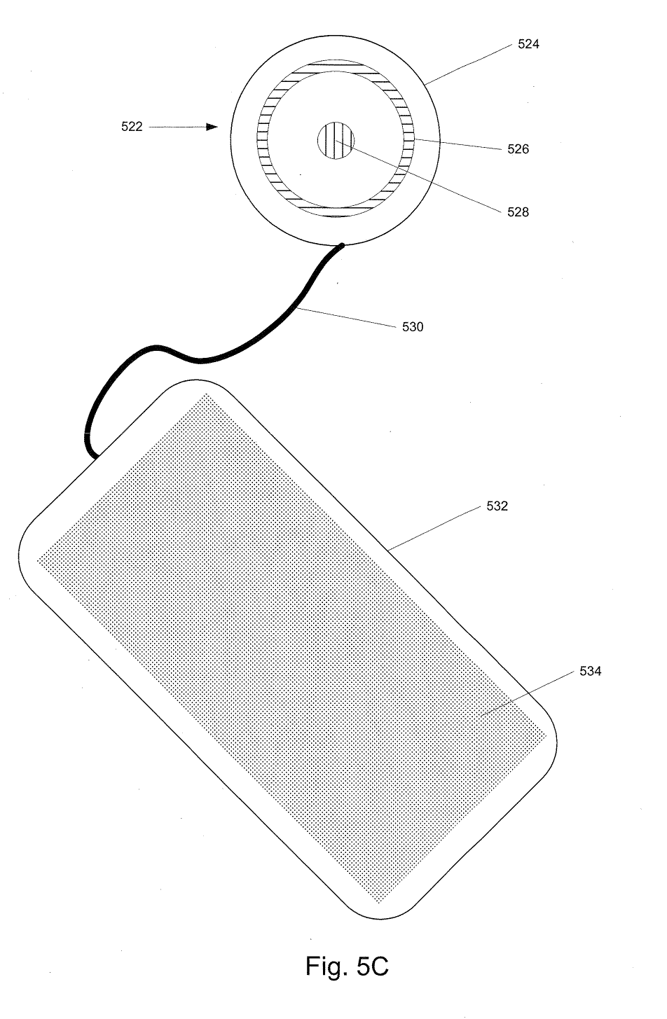

Intelligent asset management tag 400 is shown in perspective in FIG. 4. Tag body 402 has deployed at one end a tag identification connector 404. Tag identification connector 404 has a mental ring 406 and a tag contact 408. In the embodiment shown in FIG. 4, tag body 402 is preferably made of TYVEK paper, allowing for flexibility. In one embodiment of the present invention, tag 400 is approximately 13 mm wide. FIGS. 5A-5B show a more detailed view of tag 500. FIG. 5A shows one side of tag 500 including tag body 502, identification circuit 504 and tag identification connector 506 with a metal ring 508 and a tag contact 510. FIG. 5B shows the opposite side of tag 500. Adhesive 512 and barcode 514 are provided on this opposite side. In an alternative embodiment, tag body 402 may be made of flexible plastic. In particular, the tag 402 body may be formed as a short cable rather than a TYVEK strip, and may be attached to the server by a number of conventional means, including adhesive and magnetic means. Identification circuit 504 contains an identification number.

FIG. 5C shows another embodiment of the present invention, where the asset management tag 520 include head 522 having a housing 524, a metal ring 526 and a tag contact 528. The head 522 is attached to a tether 520 which is in turn attached to a stick pad 532 having a adhesive 534 deployed on the stick pad 532. The housing 524 contains the identification circuit (not shown) behind and electrically coupled to the tag contact 528 and the metal ring 526. The identification circuit contains an identification number. The tether 530 may be approximately seven inches in length. The head 520 may be approximately 0.5 cm in radius and approximately 1 cm in depth. In a preferred embodiment, the tag contacts 510 or 528 are made of gold. In operation the metal ring 526 is the ground connection and the contact 528 is the data connection for a 1-wire circuit when the asset tag 520 is attached town asset management strip.

In an alternative embodiment of the present invention, the circuit loop connecting the identification circuit to the metal ring and the contact is extended the length of the tether 530. This allows notification if the tether is cut.

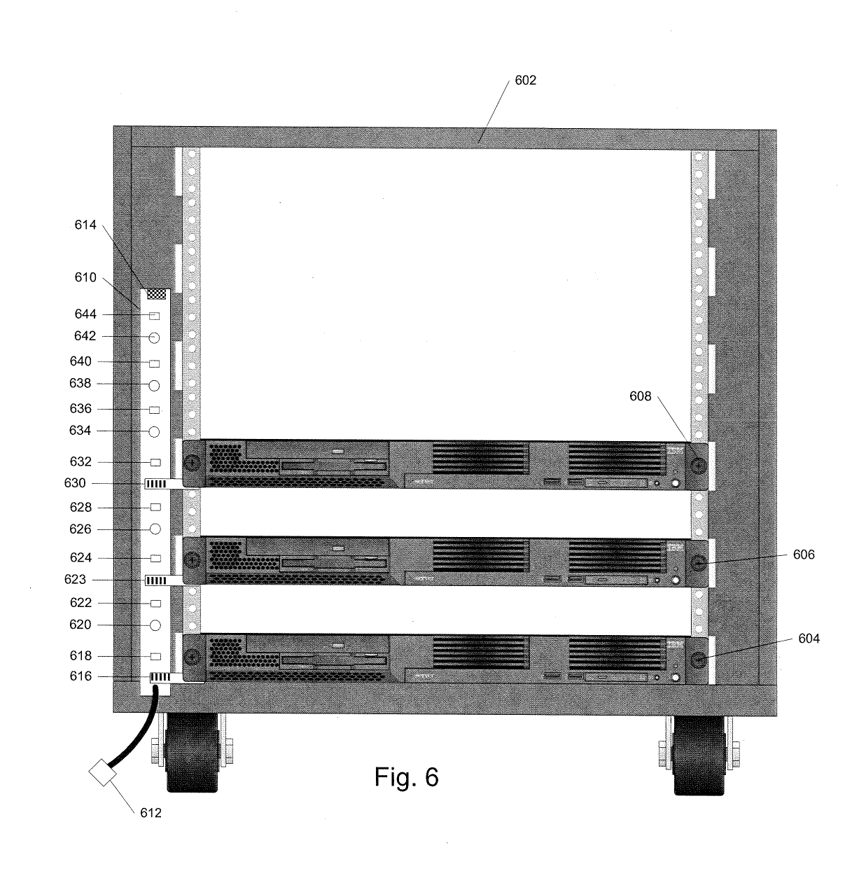

FIG. 6 shows an asset strip 610 and asset tags 616, 623, 630 in use. Servers 604, 606, and 608 are deployed in server rack 602. Strip 610 is attached to a front post of rack 602. Serial data connector and jack 612 is shown at the bottom of asset strip 610. Tag 616 is shown removably coupled to asset strip 610 via identification connector (not shown), and to server 604. The corresponding LED 618 is above tag 616. Note that the LEDs are shown through the translucent material in FIG. 6. Identification connector 620 and associated LED 622 are shown above LED 618. Tag 623 and associated LED 624 are also shown, where tag 623 is attached to server 606 and removably coupled to an identification connector (not shown). Above LED 624 is identification connector 626 and associated LED 628. Above LED 628 is asset tag 630 and associated LED 632, where the asset tag 630 is removably coupled to the asset strip 610 at an identification connector (not shown) and attached to server 608. Identification connector 634 and associated LED 636, identification connector 638 and associated LED 640, and identification connector 642 and associated LED 644 are shown above LED 632. Inter-strip connector 614 is shown at the top of asset strip 610.

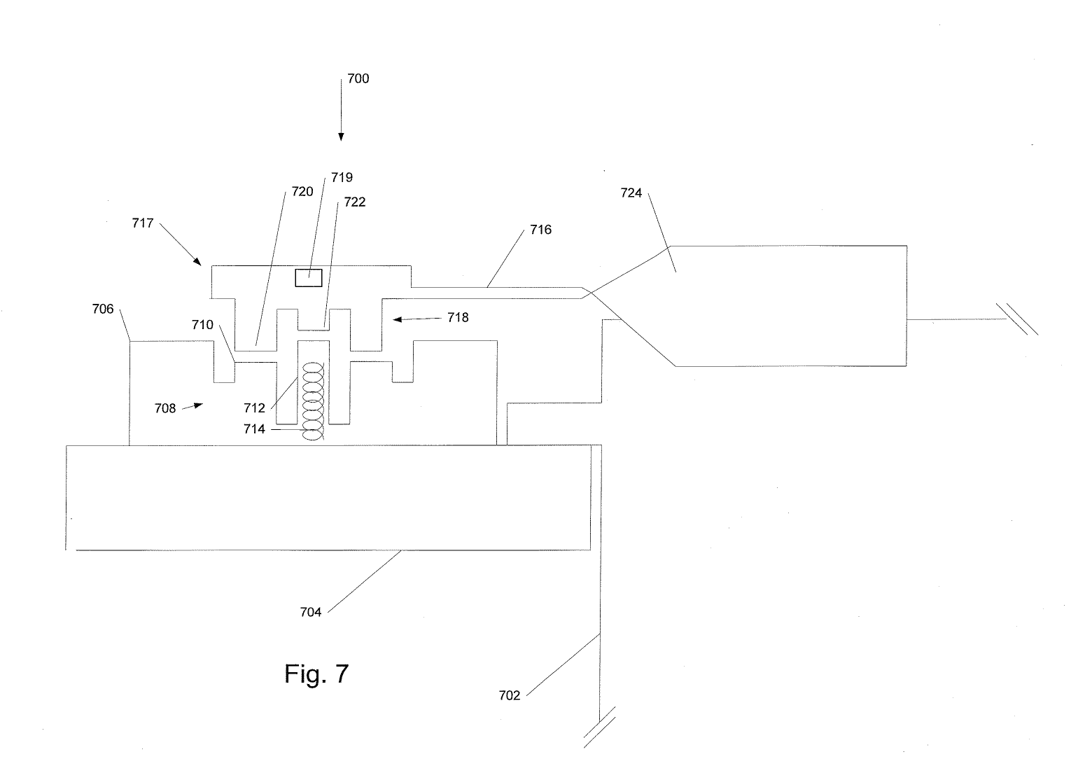

FIG. 7 shows a cut away view 700 as seen from the bottom of a server 702 mounted on a rack post 704, looking up. The cut is through the middle of an identification connector 708 of asset strip 706 and its associated tag 715. identification connector 706 has a magnetic ring 710 and a spring-loaded contact 712 urged forward by spring 714. Tag 715 has a tether 716 and a tag identification connector 718 with a metal ring 720 and a contact 722. Pad 724 of tag 715 is shown attached to server 702 (for example, by adhesive). Tag housing 717 supports the identification connector 718 and contains identification circuit 719 which is electrically coupled to metal ring 720 and contact 722. Note that tag tether 716 is flexible, thereby allowing the lower body 724 to be horizontal plane while the rest of the tag is in a vertical plane. In operation, metal ring 720 is attracted to a magnetic ring 710 which pushes the contact 722 against the spring contact 712. This insures a reliable electrical connection can be made between identification connector 708 and tag identification connector 718.

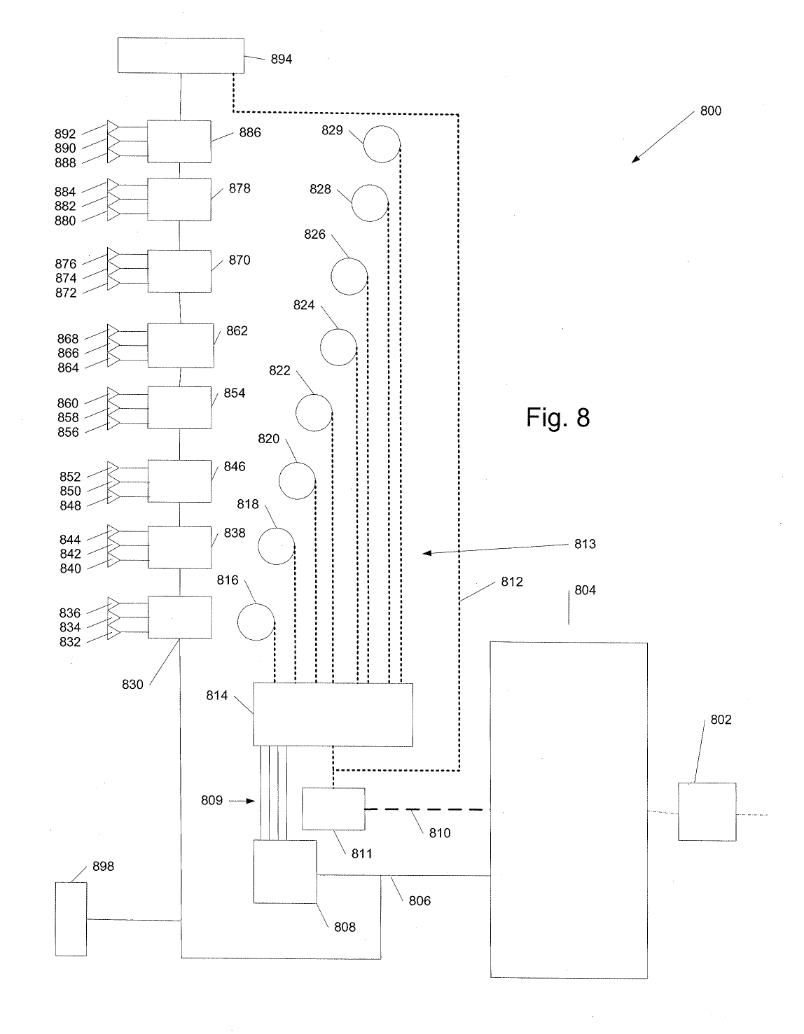

FIG. 8 shows a schematic diagram of the electrical system of an asset strip 800 according to an embodiment of the present invention. Microcontroller 804 is the primary controller for asset strip 800. It is coupled to serial protocol interface 802 which is in turn coupled to a jack such as an RJ45 jack (not shown). Serial protocol interface 802 may provide a RS-232 protocol interface. Microcontroller 804 is coupled to 1-wire converter 811 via I2C bus 810. Microcontroller 804 is also coupled to an SPI bus 806. SPI bus 806 represents multiple wires to carry a Serial Peripheral Interface. SPI bus 806 is coupled to shift register 808. Shift register 808 is coupled to multiple connectors 809 which are in turn connected to analog multiplexer 814. One wire converter 811 is coupled to 1-wire bus 812. 1-Wire bus 812 is in turn coupled to analog multiplexer 814. Analog multiplexer 814 is individually coupled to eight contacts 816-829 via separate 1-Wire branch buses 813. Each contact 816-829 is a spring contact in an identification connector as described in FIGS. 1 through 7. SPI bus 806 is also connected to a daisy chain of LED controllers 830, 838, 846, 854, 862, 870, 878 and 886. Each LED controller is associated with one of the contacts 816-829. LED controller 830 is associated with contact 816 in the 1U position. LED controller 838 is associated with contact 818 in the 2U position. LED controller 846 is associated with contact 820 in the 3U position. LED controller 854 is associated with contact 822 in the 4U position. LED controller 862 is associated with contact 824 in the 5U position. LED controller 870 is associated with contact 826 in the 6U position. LED controller 878 is associated with contact 828 in the 7U position. LED controller 886 is associated with contact 829 in the 8U position.

Each LED controller is coupled to a red LED, a green LED, and a blue LED. LED controller 830 is coupled to red LED 832, green LED 834 and blue LED 836. The LED controller 838 is coupled to red LED 840, green LED 842 and blue LED 844. LED controller 846 is coupled to red LED 848, green LED 850, and blue LED 852. LED controller 854 coupled to red LED 856, green LED 858, and blue LED 860. LED controller 862 is coupled to red LED 864, green LED 866, and blue LED 868. LED controller 870 is coupled to red LED 872, green LED 874, and blue LED 876. A LED controller 878 is coupled to red LED 880, green LED 882, and blue LED 884. A LED controller 886 is coupled to red LED 888, green LED 890, and blue LED 892. LED controllers 830-886 are coupled to one another in a daisy chain manner. LED controller 886 is coupled to inter-strip connector 886. 1-Wire bus 812 is also coupled to inter-strip connector 894.

In operation microcontroller 804 sends and receives information over connection 810 which is converted into a 1-Wire data format by converter 811. Simultaneously, microcontroller 804 sends control signals over SPI bus 806 to shift register 808. Shift register 808 converts the serial control information into parallel control information sent over connections 809. Parallel control information 809 controls analog multiplexer 814 by enabling analog multiplexer 814 and by selecting one of eight contacts 816-828 with which to communicate via 1-Wire connection. The 1-Wire bus 812 forms a single bus only and is coupled only to the branch of branch bus 813 selected by control data sent over connection 809. If analog multiplexer 814 is set to disable, then no branch bus is coupled to the 1-Wire bus 812.

The microcontroller 804 can establish a 1-Wire connection to any one of 8 contacts 816-829 or to the inter-strip connector 894. The inter-strip connector 894 is selected when the multiplexer is set to disable. In operation, if a contact such as contact 816 is in coupled with asset tag identification connector, identification data is sent over the 1-Wire bus created by the multiplexer 814. The microcontroller 804 will recognize when no information is transferred, and thus that no asset tag is present, if it selects a contact that has no tag present. Further the microcontroller 804 can associate the presence of identification data or lack thereof with a position determined by which of the 8 contacts was accessed. For example identification information from contact 816 would be associated with a 1U position while identification information from contact 828 would be associated with an 8U position. The microcontroller 804 can poll the contacts 816-828 in a round robin fashion or any other fashion to determine the state of all the identification connectors of the asset strip 800.

Further, in operation, microcontroller 804 can activate LEDs associated with the various contacts 816-829. Again, the various contacts 816-829 are the spring contacts of identification connectors of an asset strip. Microcontroller 804 accesses these LEDs via LED controllers 830, 838, 846, 854, 862, 870 and 878. So, for example, if no identification information is present at contact 816, and therefore no asset tag is present, then a red LED 832 can be made to activate by microcontroller 804 issuing instructions to LED controller 830. If an asset tag is present, a green LED could be made to activate. The possible LED behaviors are numerous and are user programmable. For example an LED could be made to blink from instructions issued over the serial protocol interface 802 to the asset strip 800 from an external source to indicate that a particular server is to be serviced by a technician

In addition, tilt sensor 898 is present and connected to SPI bus 806. Tilt sensor 898 can indicate to the microcontroller 804 is the asset strip 800 is upside down. The microcontroller 804 can then adjust its location information accordingly to continue to report accurate position information.

The various components described are well known in the art. More particularly, in one embodiment of the present invention microcontroller 804 is preferably a STM32F103 medium-density performance line ARM-based 32-bit MCU available from STMicroelectronics. Serial interface 802 is preferably a SN75C3232E two-channel RS-232 1-mbit/s line driver/receiver available from Texas Instruments. Shift register 808 is preferably a M74HC595 8 BIT SHIFT REGISTER from STMicroelectronics. Analog multiplexer 814 is preferably a NLAS4051 analog Multiplexer/Demultiplexer available from ON Semiconductor. Each of LED controllers 830, 838, 846, 854, 862, 870 and 878 is preferably a A6281 3-Channel Constant Current LED Driver available from Allegro Microsystems Inc. The 1-Wire converter 811 is preferably a DS2482-100 I2C-TO-1-WIRE bridge device available from Dallas Semiconductor Corp. that interfaces directly to I2C masters to perform bidirectional protocol conversion between the I2C master and any downstream 1-Wire slave devices.

1-Wire is a device communications bus system designed by Dallas Semiconductor Corp. that provides low-speed data, signaling, and power over a single signal. 1-Wire is similar in concept to I2C, but with lower data rates and longer range. One distinctive feature of the bus is the possibility to use only one data wire (and ground return).

It will be appreciated that many alternatives to the illustrative embodiment are possible. For example, the microcontroller 804 can absorb one or all of the functions of the various ancillary integrated circuits such as shift register 808, 1-Wire converter 811 and analog multiplexer 814. Further, alternatives to the SPI bus 806 can be easily considered, such as I2C. Alternatively, the functions of microcontroller 804 may be spread among a number of components. The connections such as connections 806 and 810 may have multiple components between the disclosed components creating an indirect connection. It is understood that SPI Bus 806 and I2C bus 810 do not represent single wires, but a group of wires necessary to implement the functions of carrying data as described. For example, in the illustrative embodiment, connection 806 is a SPI bus, which commonly requires 4 wires to implement, but may require less depending on implementation. Similarly I2C bus 810 requires multiple wires.

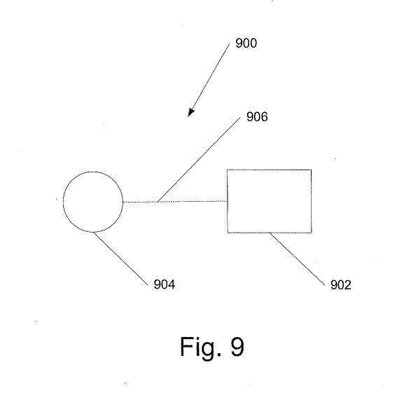

FIG. 9 shows a schematic diagram of the electrical system of an asset tag 900. Identification Chip 902 is shown electrically coupled to contact 904. Contact 904 is the contact of an asset identification connector. In one embodiment of the present invention, Identification Chip 902 may preferably be a DS2401 Silicon Serial Number chip available from Dallas Semiconductor Corp.

The DS2401 enhanced Silicon Serial Number is a low-cost, electronic registration number that provides a unique identity which can be determined with a minimal electronic interface (typically, a single port pin of a microcontroller). Data is transferred serially via the 1-Wire protocol that requires only a single data lead and a ground return. Power for reading and writing the device is derived from the data line itself with no need for an external power source.

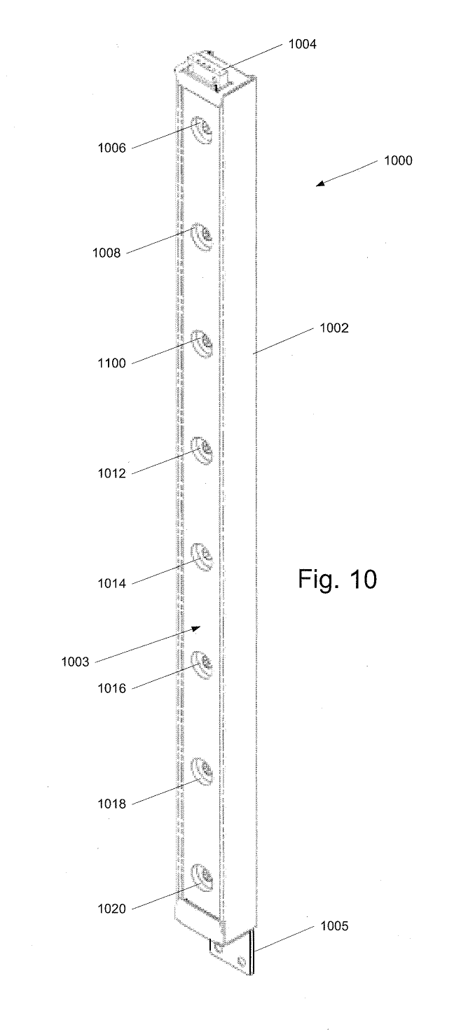

FIG. 10 shows a slave intelligent asset strip (“slave strip”) 1000. Enclosure 1002 has identification connectors 1006-1020 positioned in apertures in the translucent front 1003. At the top end of the enclosure is male inter-strip connector 1004 and female mechanical locking mechanism (not shown). At the bottom of the enclosure 1002 is female inter-strip connector (not shown) and male mechanical locking mechanism 1005. In operation, a first slave strip connects a top end with a male inter-strip connector to a bottom end of a second slave strip with a female inter-strip connector. Simultaneously, the female mechanical connector at the top end of the first slave strip will join the second slave strip via the male mechanical locking mechanism. A strip such as strip 100 of FIG. 1 can also join a second slave strip as if the first slaves strip in this description using inter-strip connector 124.

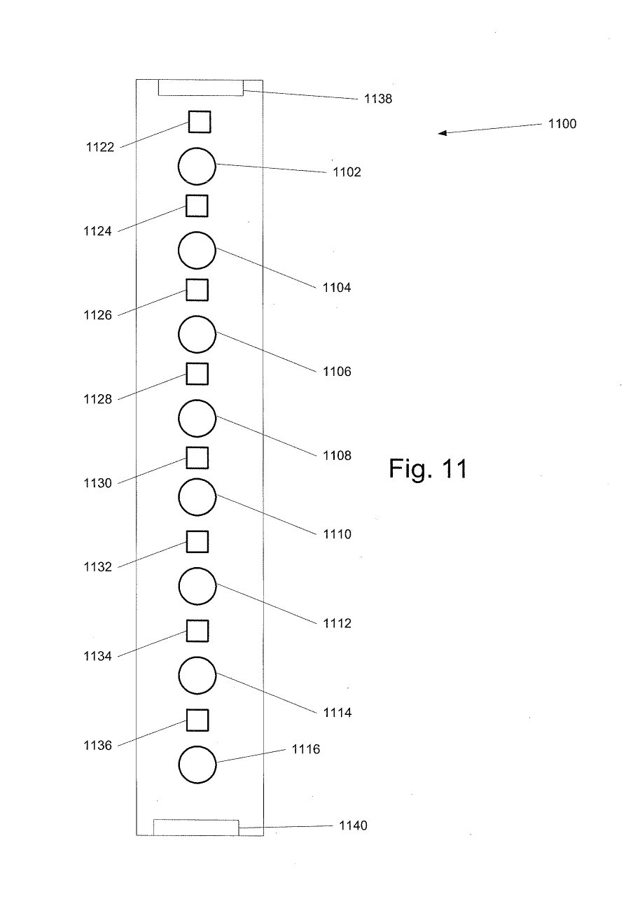

FIG. 11 shows a more detailed front view of a slave asset strip 1100 without the translucent front 1003 as seen in FIG. 10. identification connectors 1102-1116 are shown, as are multicolor LED's 1122-1136. Inter-strip connector 1138 and 1140 are also shown. It should be obvious to one skilled in the art that translucent front 1003 can have additional apertures through which LEDs 1122-1126 could be seen, and that therefore the translucent material of fraud 1003 can be replaced by an opaque material. In a preferred embodiment, a translucent material is used as allows viewing the LEDs 1122-1126 while providing protection from the environment.

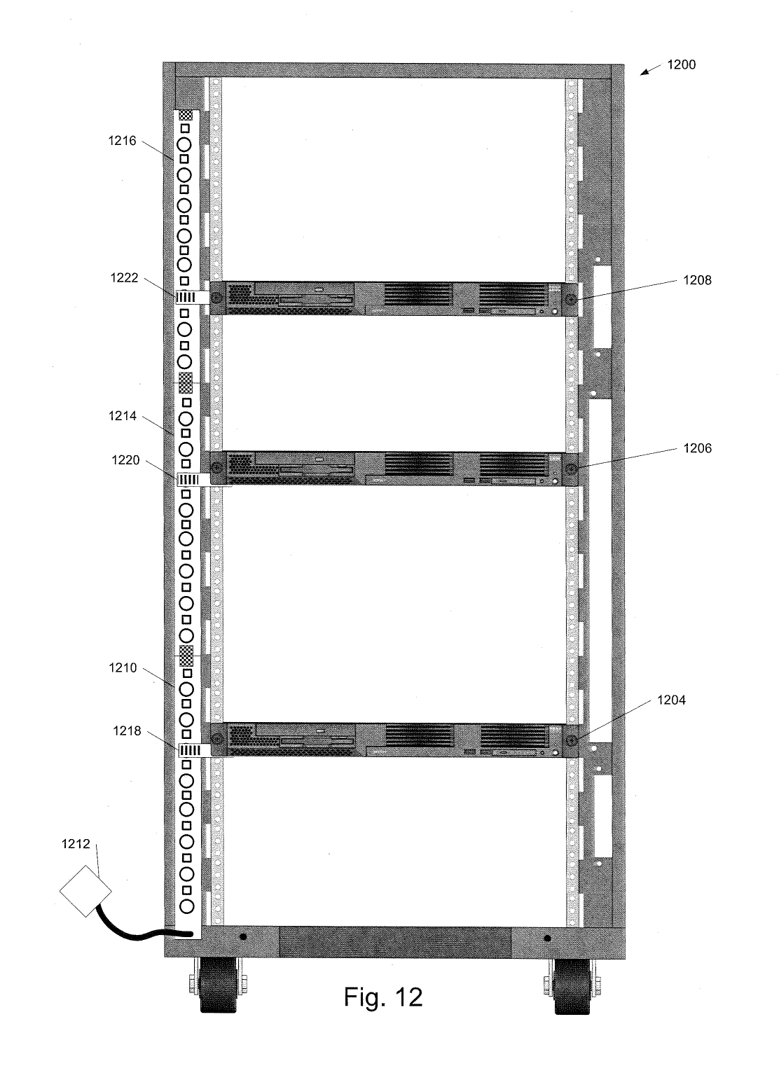

FIG. 12 shows a rack 1200 having 3 servers 1204, 1206, and 1208 mounted. Intelligent asset management strip 1210 with serial connector 1212 is joined to slave strip 1214, which is in turn joined to slave strip 1216 as described above. Strip 1210 acts as a master strip to slave strips 1214 and 1216 in a manner further described below. Tag 1218 attaches server 1204 to strip 1210 at an identification connector at the 6U position. Tag 1220 attaches server 1206 to asset strip 1214 at an identification connector at the 14U position. Tag 1222 attaches server 1208 to strip 1216 and an identification connector at the 19U position.

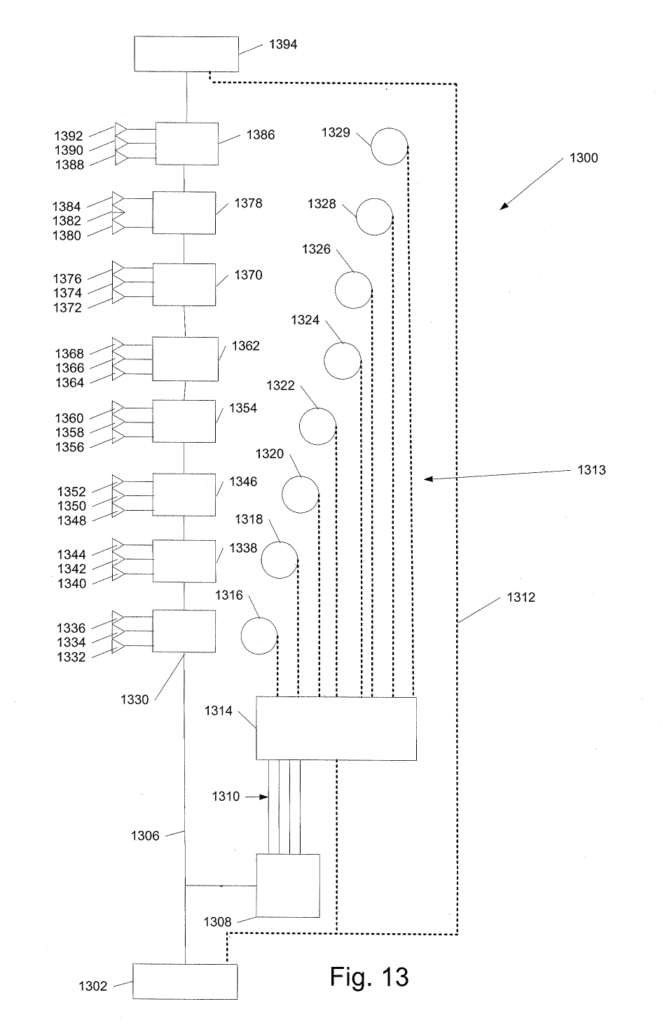

FIG. 13 shows a schematic diagram of the electrical system of slave strip 1300. Inter-strip connector 1302 is coupled to SPI Bus 1306 and 1-Wire bus 1312. These buses are coupled to similar buses in a master strip or another slave strip through inter-strip connector 1302. Coupled to SPI bus 1306 is shift register 1308. Shift register 1308 is coupled to analog multiplexer 1314 via connectors 1310. Also coupled to analog multiplexer 1314 is 1-Wire bus 1312. Shift register 1308 translates serial data into parallel control data to analog multiplexer 1314 over connectors 1310.

1-Wire bus 1312 is in turn coupled to analog multiplexer 1314. Analog multiplexer 1314 is individually coupled to the eight contacts 1316-1329 via separate 1-Wire branches 1313. Each contact 1316-1329 is a spring contact in an identification connector as described previously. SPI bus 1306 is also coupled to a daisy chain of LED controllers 1330, 1338, 1346, 1354, 1362, 1370, 1378 and 1386. Each LED controller is associated with a contact 1316-1329. LED controller 1330 is associated with contact 1316 in the 1U position. LED controller 1338 is associated with contact 1318 in the 2U position. LED controller 1346 is associated with contact 1320 in the 3U position. LED controller 1354 is associated with contact 1322 in the 4U position. LED controller 1362 is associated with contact 1324 in the 5U position. LED controller 1370 is associated with contact 1326 in the 6U position. LED controller 1378 is associated with contact 1328 in the 7U position. LED controller 1386 is associated with contact 1329 in the 8U position. Each LED controller is coupled to a red LED, a green LED, and a blue LED. LED controller 1330 is coupled to red LED 1332, green LED 1334 and blue LED 1336. The LED controller 1338 is coupled to red LED 1340, green LED 1342 and blue LED 1344. LED controller 1346 is coupled to red LED 1348, green LED 1350, and blue LED 1352. LED controller 1354 coupled to red LED 1356, green LED 1358, and blue LED 1360. LED controller 1362 is coupled to red LED 1364, green LED 1366, and blue LED 1368. LED controller 1370 is coupled to red LED 1372, green LED 1374, and blue LED 1376. A LED controller 1378 is coupled to red LED 1380, green LED 1382, and blue LED 1384. LED controller 1386 is coupled to red LED 1388, green LED 1390, and blue LED 1392. Each of LED controllers 1330-1386 is coupled to one another in a daisy chain manner. LED controller 1386 is coupled to inter-strip connector 1386. 1-Wire bus 1312 is also coupled to inter-strip connector 1394.

In operation, a microcontroller of a master strip such as microcontroller 804 provides the serial data to control shift register 1308 and the LEDs associated with the contacts 1330-1386. The 1-Wire bus 812 is continued to 1-Wire bus 1312 as one continuous bus via inter-strip connectors 894 and 1302. Thus, by providing serial data to shift register 1308 which then translates to control signals sent over connectors 1310 to analog multiplexer 1314 which then selects which of the 1-Wire branches 1313 and therefore which of the contacts 1316-1329 is elected for a connection to the 1-Wire bus 1312. The serial data over SPI bus 1306 also controls contacts 1330-1386. Thus, in operation, slave strip 1300 is similar to strip 800 except that the microcontroller 804 is required for operation of the slave strip 1300. By sending serial data over SPI bus 1306, which is in turn coupled to the SPI bus 806, the microcontroller 804 can enable and/or select which of the contacts 1330-1386 are connected to the 1-Wire bus. In a case where multiple slave strips are coupled to a master strip in a daisy chain form, the microcontroller 804 can deactivate all of the analog multiplexers such as analog multiplexer 1314 except for one in order to create a single 1-Wire bus from the 1-Wire converter 811 to a contact 1316 through 1329.

In alternative embodiment of the present invention multiplexers 814 and 1314 become 8 point 1-wire controllers. Each 8 point 1-wire controller is connected to SPI 806 or 1306. In this implementation 1-wire buses 812 and 1312 are eliminated, as is 1-wire converter 811. While this implementation requires more expense, it more quickly polls the contacts 816-829 and 1316-1329.

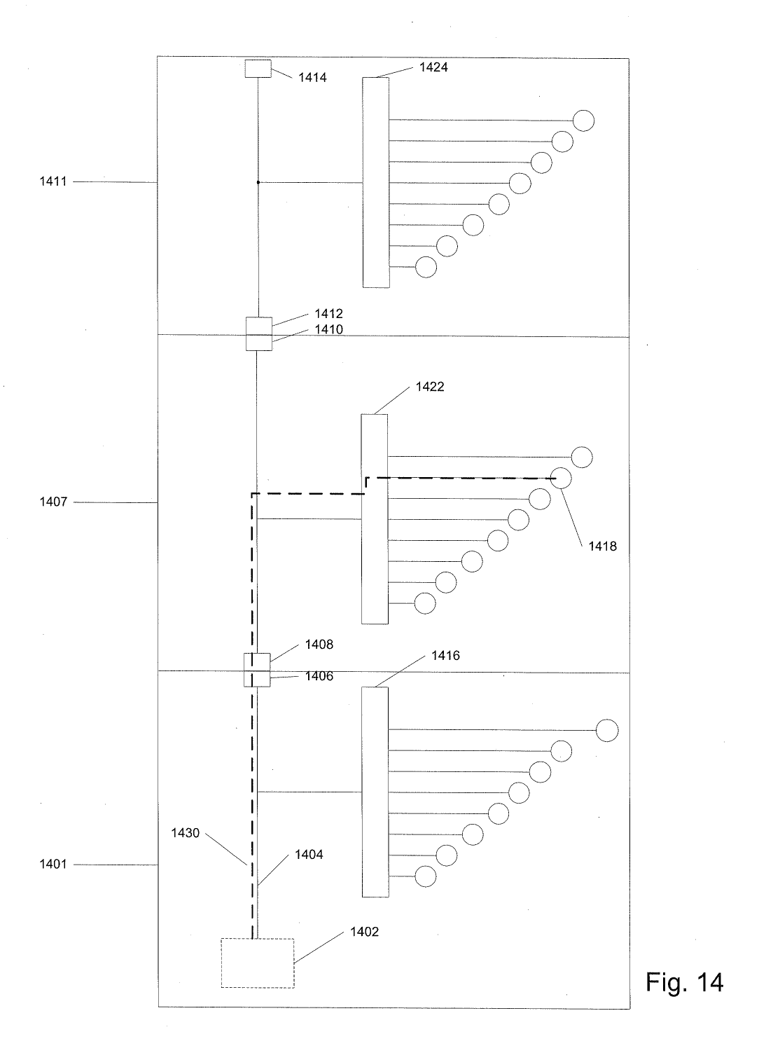

FIG. 14 illustrates how 1-Wire buses of the slave strips may be dealt with. FIG. 14 shows only the elements necessary for making the 1-wire connection, and is not drawn to scale but rather is to show the topology of the 1-wire connections. The control hardware 1402 which includes the microcontroller and the 1-wire converter of the master strip is shown coupled to the inter-strip connector 1406 and the multiplexer 1416 via 1-wire connection 1404. The slave strip 1407 connects to the master strip 1401 via bottom inter-strip connecter 1408. The inter-strip connecter 1408 allows the 1-wire connection 1404 to be extended to the coupled multiplexer 1422 and the top inter-strip connecter 1410. Another slave strip 1411 is connected by bottom inter-strip connecter 1412 of slave strip 1407. The bottom inter-strip connecter 1412 is coupled to multiplexer 1424 and top inter-strip connecter 1414 via 1-wire connection 1404. In operation multiplexers 1416 and 1424 are disabled. Multiplexer 1422 is set to select contact 1418 or the eight contacts attached to multiplexer 1422 via shift register (not shown). The shift register receives these instructions over the SPI bus (not shown) which is also connected through the inter strip connectors from the microcontroller that is part of the control hardware 1402. In this manner, in a three strip extended strip, a 1-Wire connection 1430 is effectively made with the contact 1418 of the slave strip 1407 as chosen by the master strip control hardware. Further, the microcontroller knows which strip has been selected and which contact has been selected, thus allowing the association of the logical address of the contact and its physical position.

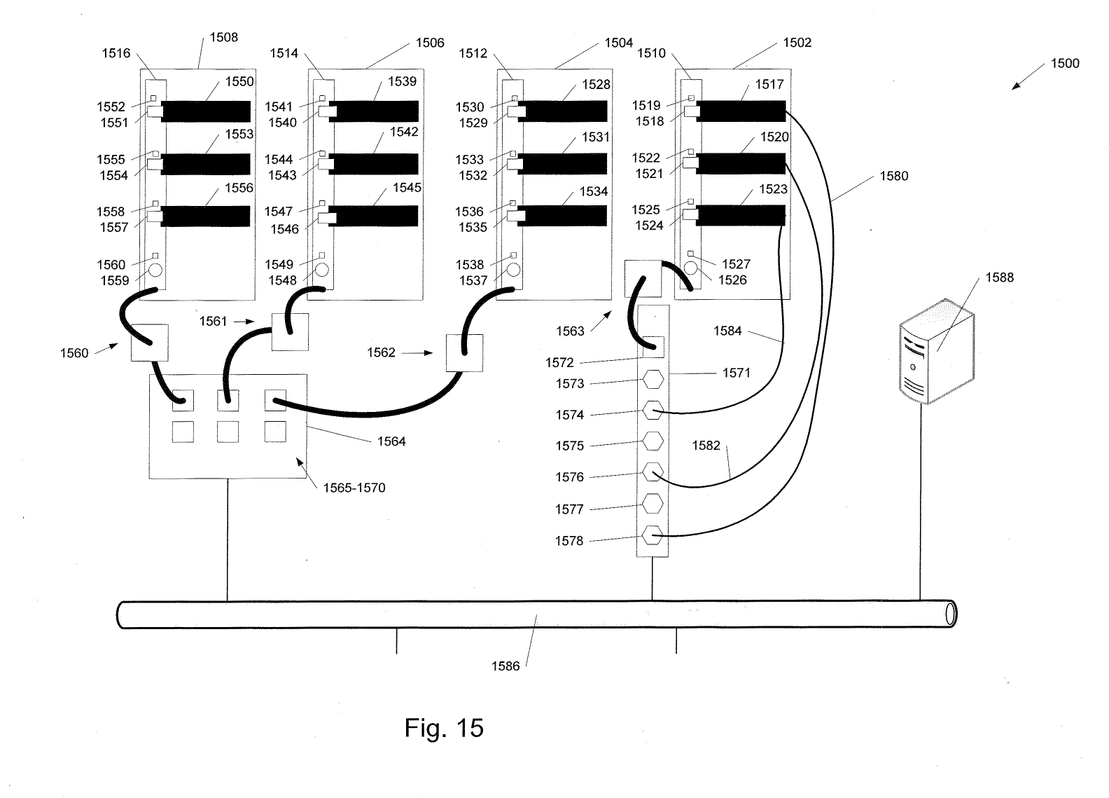

FIG. 15 shows a portion of a data center 1500. Racks 1502 1504 1506 and 1508 are shown each having an asset strip 1510, 1512, 1515 and 1516, respectively. Mounted on rack 1502 is server 1517 coupled to asset strip 1510 by asset tagged 1518 underneath the corresponding LED 1519. Server 1520 is mounted on rack 1502 and is coupled to asset strip 1510 by asset tag 1521 which is underneath LED 1522. Server 1523 is mounted on rack 1502 and is coupled to asset strip 1510 by asset tag 1524 underneath LED 1525. Identification connector 1526 is open and underneath LED 1527. In FIG. 15 for ease of illustration only 4 rack unit positions are shown on each server 1502-1508. In rack 1504 servers 1528, 1531, 1534 are attached to asset strip 1512 the asset tags 1529, 1532, 1535 respectively. Each of these asset tags 1529, 1532, 1535 is underneath corresponding LED 1530, 1533, 1536 respectively. Identification connector 1537 is not occupied by asset tag and is underneath corresponding LED 1538. Similarly, in rack 1506 servers 1539, 1542 and 1545 are attached to strip 151*4 by asset tags 1540, 1543 and 1546 respectively. Asset tags 1540, 1543 and 1546 are underneath corresponding LED 1541, 1544, and 1547 respectively. identification connector 1548 is not coupled to an asset tag and is underneath corresponding LED 1549. Similarly, in rack 1508 servers 1550, 1553 and 1556 are attached to asset strip 1516 by asset tags 1551, 1554 and 1557 respectively. Asset tags 1551 1554 and 1557 are underneath corresponding LEDs 1552 1555 and 1558 respectively. Identification connector 1559 is not coupled to an asset tag and is underneath corresponding him the 1560. Serial connection 1560 includes the cable and jack integral to the asset strip and a connecting cable leading to a jack 1565 in SNMP Gateway 1564. Similarly, serial connections 1561 and 1562 connect asset strips 1515 and 1512 to jacks 1566 and 1567 in SNMP Gateway 1564. In one embodiment of the present invention, the serial connections are RS232 protocol connections. Serial connection 1563 connects power distribution unit (PDU) 1571 to asset strip 1510 via jack 1572. Electrical outlets 1573-1578 are shown on the PDU 1571. Power connection 1580 connects server 1517 to outlet 1578. Power connection 1582 connects next server 1520 to outlet 1576. Power connection 1584 connects server 1523 to outlet 1574. SNMP Gateway 1564 and PDU 1571 are both coupled to network 1586. Also coupled to network 1586 is management server 1588, a server running data center infrastructure management software.

In operation, management server 1588 communicates bi-directionally with asset strips 1510-1516 via SNMP protocol over network 1586. The SNMP protocol runs on top of a UDP/IP protocol. SNMP Gateway 1564 and PDU 1571 both act as translation mechanisms for SNMP to a simple serial protocol such as RS 232 for communicating with asset strips 1510-1516. For example, when tag 1529 is coupled to asset strip 1512 and server 1528, a microcontroller such as microcontroller 804 provided in asset strip 1512 may poll each of the various spring contacts of the identification connectors of asset strip 1512 for an identification number. If the connection between the tag 1529 and the asset strip 1512 is present, the identification number is then transmitted down a 1-Wire bus such as 1-Wire bus 812 to the 1-Wire converter 811, at which point the identification number is transferred to the microcontroller 804 over the I2C bus. The microcontroller 804 will provide the identification number and the location along the strip 1512 of the server 1528 to SNMP Gateway 1564. SNMP Gateway 1564 will then add the rack number identifying the physical rack 1504 on which asset strip 1512 is located. This rack number will have been previously loaded into the SNMP Gateway 1564. This identification number, rack number and U position (vertical position) are then sent to management server 1588. Management server 1588 will have the asset management record of server 1528 including the identification number of server 1528. Therefore through the identification number the rack number and vertical position of server 1528 may be associated with the asset management record of the server 1528 which includes all of its salient attributes. Thus the physical location of server 1528 is now correlated with this information of the asset management record. The record can include information such as the IP address of the server, the MAC address of the server, the server serial number, and other identifying information. On receiving the identification number of server 1528, management server 1588 will signal LED 1530 to display a signal indicating a successful connection, for example a green light. This correlation has occurred in an automated manner, and is maintained constantly in an automated matter. Similarly, servers 1550 1553, 1556, 1539 1542 and 1545 of racks 1508 and 1506 will also have their physical location correlated with an asset management record. The PDU 1571 will behave similarly to SNMP Gateway 1564, allowing servers 1517, 1520 and 1523 of rack 1502 to have their position correlated to an asset management record in management server 1588.

It will be obvious to one skilled in the art that the rack number could be located in the asset strips 1510-1516 or in the DCIM on management server 1588.

The asset strips 1510-1516 can be used in a variety of ways during the installation and maintenance of servers. For example, management server 1588 can instruct LED 1538 on asset strip 1512 to emit red light, or blink, or perform some other user operated signal to indicate a position (i.e., connector 1537) at which a new server should be installed. The asset strips 1510-1516 can also be useful in performing repairs, maintenance and other actions requiring presence at the physical server. For example if server 1531 requires maintenance, the technician will know the rack number and vertical location of the server 1531. Moreover, LED 1533 can emit light of a user-determined maintenance color, for example such as a blue light. In this manner, the technician performing maintenance can easily find the appropriate server among hundreds if not thousands of servers.

The advantageous over other methods of correlation and numerous. The embodiments of the present invention operate without the need for batteries. The physical location is confirmed down to the U level of resolution. The errors and effort that are inevitable in manually entering identification numbers and physical locations in the DCIM are avoided.

In an alternative embodiment of the present invention gateway 1564 also handles JSON RPC, command line interface, and other protocols in addition to SNMP. In yet another embodiment of the present invention the asset strip 15160-1516 incorporate SNMP protocols within them obviating the need for the PDU 1571 and the gateway 1564.

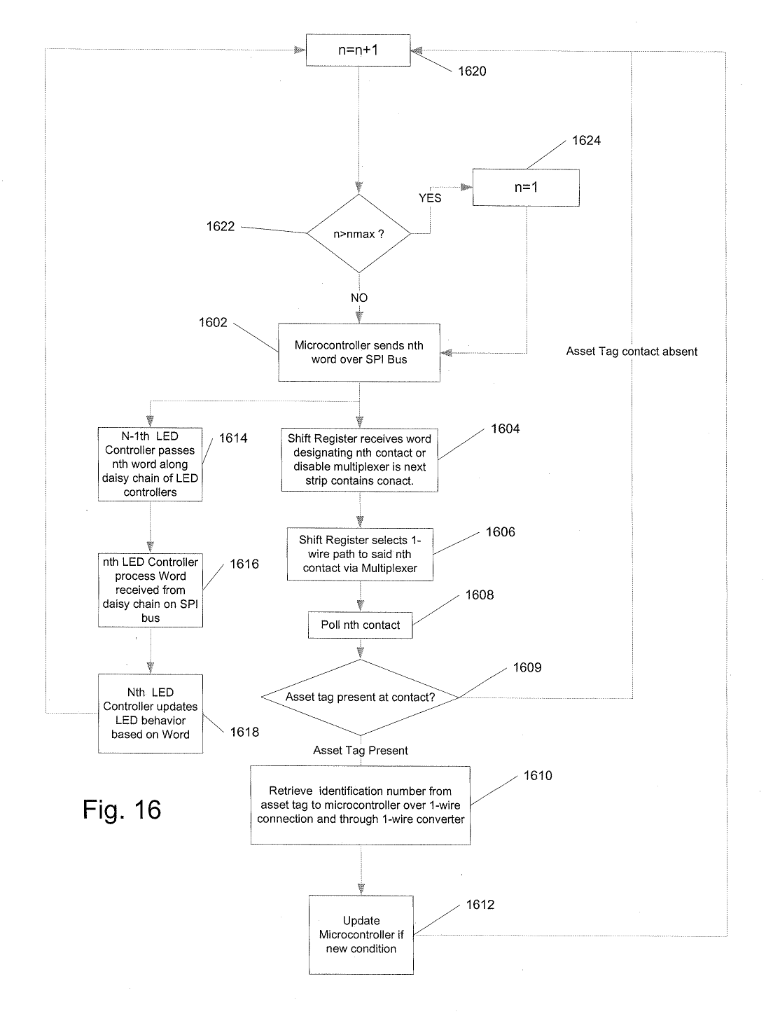

FIG. 16 shows one procedure for operation of an embodiment of the present invention. The serial data from microcontroller 804 over the SPI bus 806 is preferably provided as 32-bit words with 8 bits for the control of the red LED, 8 bits for the control of the green LED, 8 bits for the control of the blue LED all through the LED controller and the final 8 bits for the control of analog multiplexers through the shift registers. A different word is sent for each controller at the rack positions 1U-nU of the strip, where n is the length of the total asset strip in U units. STEP 1602. The microcontroller polls the contacts of the strip. STEPS 1604, 1606, 1608. In other words it runs through 1-n options and when it hits 0 it resets at n=1. STEPS 1620, 1622, 1624. If a slave strip is coupled to a master strip to form an extended strip, then the microcontroller 804 continues its cycle from rack position 9U to the end of the extended strip. Simultaneously, the LED controllers 830 to 886 on SPI bus 806 will pass on any word they receive which is not the number of the word which applies to that LED controller. For example, the 4^{th} LED controller 854 will not receive words 1-3, will process word 4, and then will pass on words 5-n. Thus the daisy chain on the SPI bus 806 is implemented. STEPS 1614, 1616. As the same SPI bus 806 is connected to the shift register 808 as the LED controllers 830-886 we see the nth word will select the nth microcontroller while having LED instructions processed by the nth LED controller. STEP 1618. Thus LED and contact remain correlated. If the asset tag in not present at the contact 816-829 then no identification number is retrieved by the microcontroller. STEP 1609. If the asset tag is present then the identification number is retrieved by the microcontroller 804. STEP 1610, 1612. Note that n will have a maximum determined by the number of asset strips x*8 as entered into the microcontroller over a serial connection. Note that this process could be implemented in a number of ways obvious to one skilled in the art. In every instance where a generic server on a rack has been discussed, it is understood that any database center component could be used instead. In the case of the management server, that may be DCIM software implemented on any of a number of platforms such as a virtual machine, a single server, or multiple servers.

Daisy chaining is a method of propagating signals along a bus in which the devices are coupled in series and the signal passed from one device to the next. The daisy chain scheme permits assignment of device priorities based on the electrical position of the device on the bus.

Although the invention herein has been described with reference to particular embodiments, it is to understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An asset management system comprising
a) an asset management strip having a plurality of identification connectors;
b) at least one asset management tag having a flexible sheet with a tag identification connector deployed on the flexible sheet, one of said at least one asset tag being fixedly attached to an asset and said identification connector being coupled to an identification circuit storing identification data of the asset;
c) wherein said tag identification connector is configured to be removably coupled to one of the plurality of identification connectors; and
d) wherein said tag identification connector is configured to provide the identification data of the asset to the asset management strip when coupled to the one identification connector.

2. The asset management system of claim 1, further comprising
a) a management program running on a first server,
b) a network coupled to the asset management strip and coupled to the server;
c) wherein the asset strip is configured to provide the identification data to the management program on the server;

3. The asset management system of claim 2, further comprising
a) a rack having at least two vertical posts;
b) wherein the asset comprises a data center component mounted on the rack;
c) wherein the asset strip is mounted on one of said vertical posts of said rack; and
d) wherein said one asset tag is fixedly attached to the data center component.

4. The asset management system of claim 3, wherein the asset strip further comprises a plurality of LEDs, wherein each of the plurality of identification connectors is individually associated with at least one of the plurality of LEDs.

5. The asset management system of claim 4, wherein each of the plurality of identification connectors is associated with three of the plurality of LEDs including a red LED, a green LED, and a blue LED.

6. The asset management system of claim 4, wherein the at least one LED associated with the one identification connector is activated by the management software upon receiving the identification information of the asset provided by the asset strip.

7. The asset management system of claim 3, wherein the data center component is a second server.

8. The asset management system of claim 4,
wherein the management software is configured to identify another one of the plurality of identification connectors that is not coupled to one of the at least one asset tag, and to activate the at least one LED associated with the other one of the identification connectors to indicate an available asset position.

9. The asset management system of claim 8,
wherein the asset strip is configured to poll the plurality of identification connectors to determine a connection status for each identification connector.

10. An asset management strip comprising:
a) a plurality of identification connectors each having a magnetic ring and a contact, and each configured to removable couple to an identification circuit;
b) a microcontroller providing control signals;
c) a control bus coupled to said microcontroller for carrying the control signals;
d) a data bus coupled to the microcontroller;
e) a multiplexer coupled to the data bus and the control bus;
f) a plurality of branch data buses each coupled to the multiplexer and to one of the first number of identification connectors;
g) wherein the multiplexer couples at most one of said first number of branch data buses to said data bus at any point in time; and
h) wherein the control signals provided by said microcontroller over said control bus are used by said multiplexer to connect the at most one branch data bus to the data bus.

11. The asset management strip of claim 10, wherein the data bus is a 1-Wire bus and the branch data buses are 1-Wire buses.

12. The asset management strip of claim 11, further comprising a 1-Wire data converter coupled between said data bus and said microcontroller.

13. The asset management strip of claim 8, further comprising
a) a plurality of LED controllers, wherein a first one of said plurality of LED controllers is connected to the control bus and others of said plurality of LED controllers are coupled to the control bus in a daisy chain; and
b) a plurality of LEDs wherein, each LED is coupled to one of said LED controllers.

14. The asset management strip of claim 13, wherein each one of said LED controllers is coupled to three of the plurality of LEDs including a red LED, a green LED, and a blue LED.

15. The asset management strip of claim 13, further comprising an interstrip connector coupled to the data bus and the control bus, the interstrip connector for coupling the asset management strip to a second asset management strip.

16. The asset management strip of claim 10, further comprising coupled to serial protocol interface coupled the microcontroller.

17. A method for managing assets in an asset management system including an asset management strip having a plurality of identification connectors and at least one asset management tag having a tag identification connector and being fixedly attached to an asset and said identification connector, said tag identification connector being coupled to an identification circuit storing identification data of the asset, the method comprising the steps of:
a) determining that said tag identification connector is electrically coupled to one of the plurality of identification connectors;
b) retrieving the identification data of the asset at the one identification connector of the asset management strip via the electrically-coupled tag identification connector of the at least one asset management tag; and
c) providing the retrieved identification data to a management program of a first server over a network coupling the first server to the asset management strip.

18. The method of claim 17, wherein the least one LED is associated with the one identification connector in the asset management strip, comprising the step of:
activating the LED after retrieving the identification information.

19. The method of claim 18, further comprising the steps of:
identifying another one of the plurality of identification connectors that is not coupled to one of the at least one asset tag, and
activating the at least one LED associated with the other one of the identification connectors to indicate an available asset position.

20. The method of claim 19, further comprising the step of:
polling the plurality of identification connectors to determine a connection status for each identification connector.
